(19) United States
(12) Patent Application Publication
(10) Pub. No.: US 2025/0005321 A1
(43) Pub. Date: Jan. 2, 2025

(54) MULTI-BRANCH NEURAL NETWORKS FOR DEFECT PREDICTIONS IN INTEGRATED CIRCUIT (IC) DESIGNS

(71) Applicant: Siemens Industry Software Inc., Plano, TX (US)

(72) Inventors: Joe Kwan, Oakland, CA (US); Kareem Madkour, Cairo (EG); Asmaa Rabie, Faisal Giza (EG); Emily Thomas, Tacoma, WA (US)

(73) Assignee: Siemens Industry Software Inc., Plano, TX (US)

(21) Appl. No.: 18/344,252

(22) Filed: Jun. 29, 2023

(51) Int. Cl. G06N 3/04; G06F 30/392

(52) U.S. Cl. CPC G06N 3/04; G06F 30/392

(57) ABSTRACT

A method may include implementing a multi-branch neural network configured to predict manufacturing defects on a layer-of-interest of an integrated circuit (IC) design. The implemented multi-branch neural network may include multiple neural network branches, including a layer-of-interest branch that processes inputs of the layer-of-interest, additional design layer branches that process inputs of the other design layers of the IC design different from the layer-of-interest, and a merged branch. The merged branch may receive, as inputs, outputs of the layer-of-interest branch and the additional design layer branches, and the merged branch may be configured to output a predictor value for the IC design. The method may also include generating, through the multi-branch neural network, a predictor value for a point-of-interest located in the layer-of-interest and predicting a manufacturing defect at the point-of-interest responsive to determination that the predictor value for the point-of-interest meets a defect criterion.

### BACKGROUND

Electronic circuits, such as integrated circuits, are used in nearly every facet of modern society, from automobiles to microwaves to personal computers. Design of circuits may involve many steps, known as a “design flow.” The particular steps of a design flow are often dependent upon the type of microcircuit being designed, its complexity, the design team, and the circuit fabricator or foundry that will manufacture the circuit. Electronic design automation (EDA) applications support the design and verification of circuits prior to fabrication. EDA applications may implement various EDA procedures, e.g., functions, tools, or features to analyze, test, or verify a circuit design at various stages of the design flow.

### BRIEF DESCRIPTION OF THE DRAWINGS

Certain examples are described in the following detailed description and in reference to the drawings.

FIG. 1 shows an example of a computing system that supports multi-branch neural networks for defect predictions in integrated circuit (IC) designs.

FIG. 2 shows an example of a multi-branch neural network according to the present disclosure.

FIG. 3 shows an example architecture in which multiple output nodes of design layer branches are merged into a corresponding input node of a merge branch of a multi-branch neural network.

FIG. 4 shows an example of a multi-branch neural network that includes an IC-level branch separate from design layer branches of the multi-branch neural network.

FIG. 5 shows an example neural network branch that includes layer custom features.

FIG. 6 shows an example of logic that a computing system may implement to support multi-branch neural networks for defect predictions in IC designs.

FIG. 7 shows an example of a computing system that supports multi-branch neural networks for defect predictions in IC designs.

### DETAILED DESCRIPTION

As modern circuit designs increase in complexity and capability, verification of circuit designs and circuit manufacturing processes becomes increasingly challenging. Various factors can impact the success of IC manufacturing processes, including variations in manufacturing process parameters and IC design components that can cause defects in manufactured circuits. As used herein, a defect may refer to any portion in a circuit (e.g., a circuit design) that is defective (e.g., an improperly manufactured circuit component unintended by a circuit design or a flaw in the circuit design itself). As encompassed herein, the term defect may include care zones or other areas-of-interest in IC design that may be flagged for further consideration. The greater the number of defects present in manufactured circuit wafers, the lower the yield of the manufacturing process. As such, prediction of yield-limiting manufacturing defects in IC designs can improve the effectiveness and throughput of IC manufacturing processes.

Various conventional defect prediction techniques can be employed to analyze IC designs. Complex simulations using model-based resolution enhancement technologies (RET) can be applied to IC designs to predict defects. However, RET-based techniques can require immense computing resources and have high simulation latencies, limiting the effectiveness and efficiency of defect predictions on ever-changing IC designs. Machine learning-based inference engines can predict interactions of design patterns with manufacturing process effects. Such conventional techniques have focused on detailed modeling of physical effects from a particular portion of an IC design, such as a layer-of-interest in an IC design. In such techniques limited only to layer-of-interest analyses, the impact of neighboring and other layers adjacent to a layer-of-interest is unaccounted for, and certain manufacturing defects remain undetected.

The disclosure herein may provide systems, methods, devices, and logic for multi-branch neural networks for defect predictions in IC designs. As described in greater detail herein, the multi-branch neural network technology of the present disclosure may support prediction manufacturing defects on a layer-of-interest by augmenting layer-of-interest data with design data of multiple nearby or adjacent IC layers to reveal previously unrecognized interactions. The present disclosure may provide for neural networks to model, analyze, or otherwise process multiple layers of an IC design, and a given layer of an IC design may be analyzed, modeled, or processed in the neural network by a given branch. As used herein, such branches of a neural network configured specifically for design layer branches of a IC design may be referred to as a design layer branch of a neural network. As such, the multi-branch neural network technology described herein may provide capabilities to account for design data of multiple layers of an IC design instead of just a single layer-of-interest, including (but not limited to) adjacent layers of the layer-of-interest in the IC design.

The multi-branch neural network technology described herein can merge multiple branches that model IC design layers into a merged branch, which can thus account for the design data of multiple different layers (including the layer-of-interest) to evaluate and predict manufacturing defects at various locations on the layer-of-interest. Such merged branches may concatenate or otherwise merge outputs of the multiple design layer branches into a respectively corresponding input nodes of the merged branch, and in various ways as described herein. Training of this merged branch, combined with the training of individually modeled design layer branches may provide a single neural network architecture by which points-of-interest in a layer-of-interest can be evaluated, including through accounting for the design data of adjacent IC design layers. Thus, critical dimension values or other predictor values for points-of-interest in a layer-of-interest of an IC design can be generated by the multi-branch neural networks of the present disclosure. Through such predictor values, manufacturing defects can be predicted for IC designs with increased efficiency and accuracy.

Through the multi-branch neural networks of the present disclosure, various technical benefits and effects can be achieved. Compared to architectures or conventional defect prediction techniques that fail to consider neighboring design layer geometry effects, the multi-branch neural network technology of the present disclosure can provide defect detections with increased accuracy and completeness. Compared to layer agnostic architectures and techniques (e.g., where input features for all masks and custom features are treated indifferently), the multi-branch neural network technology of the present disclosure can provide modeling capabilities for individual IC design layers separately (e.g., through separate neural network branches) while taking into consideration inter-layer effects (e.g., through a merged branch). Such a multi-branch architecture can yield more robust and accurate defect predictions.

These and other aspects of multi-branch neural network technology according to the present disclosure and the technical benefits of such multi-branch neural network technology are described in greater detail herein.

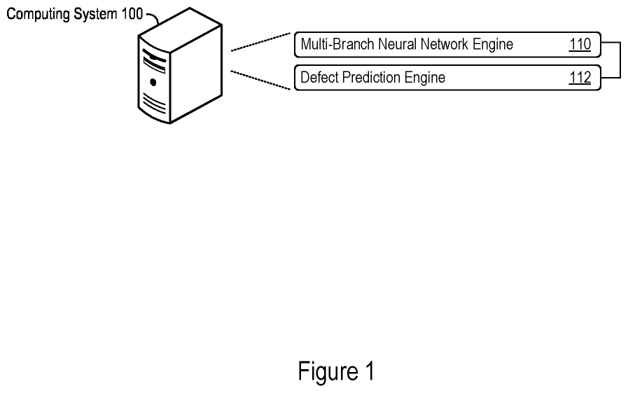

FIG. 1 shows an example of a computing system 100 that supports multi-branch neural networks for defect predictions in IC designs. The computing system 100 may take the form of a single or multiple computing devices such as application servers, compute nodes, desktop or laptop computers, smart phones or other mobile devices, tablet devices, embedded controllers, and more. In some implementations, the computing system 100 hosts, instantiates, executes, supports, or implements an EDA application or EDA system that supports circuit design and analysis, and may accordingly provide or implement any of the multi-branch neural network technology described herein.

As an example implementation to support any combination of the multi-branch neural network technology described herein, the computing system 100 shown in FIG. 1 includes a multi-branch neural network engine 110 and a defect prediction engine 112. The computing system 100 may implement the engines 110 and 112 (including components thereof) in various ways, for example as hardware and programming. The programming for the engines 110 and 112 may take the form of processor-executable instructions stored on a non-transitory machine-readable storage medium and the hardware for the multi-branch neural network engine 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the multi-branch neural network engine 110 may implement a multi-branch neural network configured to analyze multiple layers of an IC design, for example to predict manufacturing defects on a layer-of-interest of an IC design. The multi-branch neural network engine 110 may implement a multi-branch neural network in various ways, for example by constructing or training the multi-branch neural network, by configuring parameters, architecture components, or other substantive aspects of the multi-branch neural network, or by hosting, storing or otherwise accessing a multi-branch neural network. In some examples, the multi-branch neural network engine 110 may store or host a trained multi-branch neural network in support of defect predictions for IC designs.

Multi-branch neural networks implemented by the multi-branch neural network engine 110 may have particular architecture features as described herein to support analyses of multiple design layers of an IC design. For example, a multi-branch neural network may include multiple neural network branches, including a layer-of-interest branch that processes inputs of a layer-of-interest of an IC design, additional design layer branches that process inputs of other design layers of the IC design different from the layer-of-interest, and a merged branch. The merged branch of the multi-branch neural network may receive, as inputs, outputs of the layer-of-interest branch that processes the inputs of the layer-of-interest and outputs of the additional design layer branches that process the inputs of the other design layers of the IC design. The merged branch of the implemented multi-branch neural network may be configured to output a predictor value for the IC design based on the layer-of-interest branch and the additional design layer branches.

In operation, the defect prediction engine 112 may generate, through the multi-branch neural network, a predictor value for a point-of-interest located in the layer-of-interest. Any suitable predictor value is contemplated herein, and the multi-branch neural network may be configured or otherwise customized to output any number or combination of predictor values suitable for defect prediction or other forms of circuit design analysis, such as a critical dimension value, a classifier value (e.g., yes or no for a detected defect or hotspot), defect probability values, or any other suitable value, metric, label, or data for IC design defect predictions. Additionally or alternatively, and as noted herein, predictor value output(s) of multi-branch neural networks may support any type or form of multi-layer IC design analysis, including by not limited to defect prediction. In operation, the defect prediction engine 112 may also analyze a point-of-interest based on the generated predictor value, for example by predicting a manufacturing defect at the point-of-interest in the layer-of-interest of the IC design responsive to determination that the predictor value for the point-of-interest meets a defect criterion (e.g., a point-of-interest includes a feature that violates a critical dimension determined by the multi-branch neural network).

These and other aspects of multi-branch neural network technology according to the present disclosure are described in greater detail next. Various examples of multi-branch neural networks are described using defect prediction as an illustrative application, but any suitable use of multi-branch neural networks for IC design analysis is contemplated herein. For example, the multi-branch neural network technology of the present disclosure may be utilized to perform or support any type of IC design analysis, such as quality analyses, manufacture process assessments, monitoring of manufacture effects on multi-layers of an IC design, and more. Any such applications are within the scope of the multi-branch neural network technology presented herein, and multi-branch neural networks may output any suitable predictor value in support of such applications and uses.

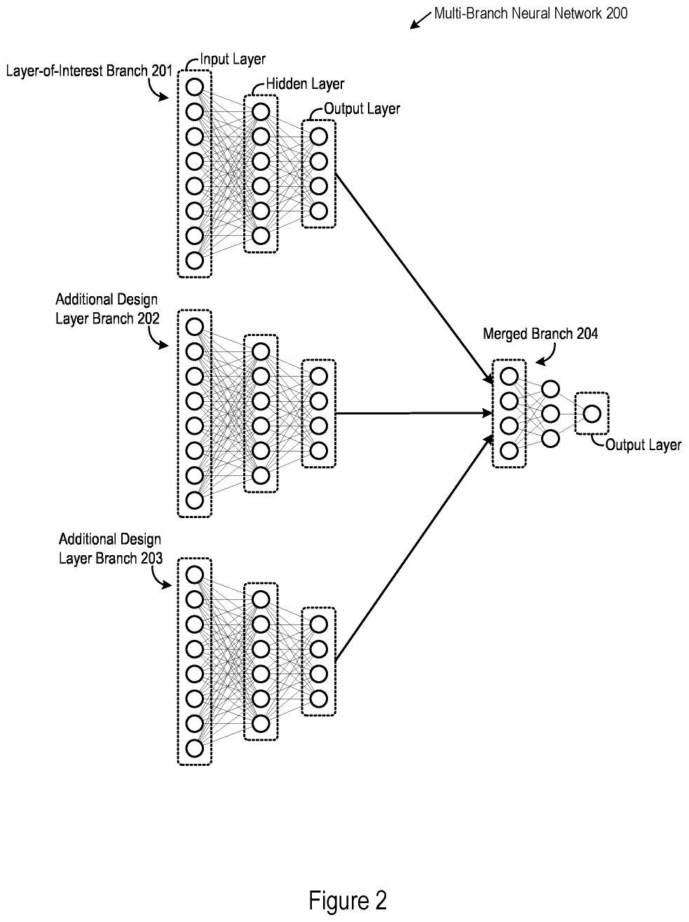

FIG. 2 shows an example of a multi-branch neural network 200 according to the present disclosure. The multi-branch neural network 200 can account for multiple design layers of an IC design by including multiple neural network branches. In the example of FIG. 2, the multi-branch neural network 200 includes a layer-of-interest branch 201, an additional design layer branch 202, and another additional design layer branch 203. The layer-of-interest branch 201 may model or account for design data of a layer-of-interest of an IC design (e.g., any selected layer of the IC design under analyses for defect predictions or other processing) as well as other design layers of the IC design. While two neural network branches for additional design layers are shown in FIG. 2, multi-branch neural networks of the present disclosure may include any number of additional neural network branches to model additional design layers of an IC design. In some examples, additional design layer branches may model adjacent layers to a layer-of-interest, and doing so may account for geometry interactions or other physical behaviors that can impact circuit manufacture, allowing for defect predictions with increased accuracy.

The multi-branch neural networks of the present disclosure may implement, incorporate, utilize, or provide any relevant machine-learning and artificial intelligence capabilities of conventional neural networks. In that regard, multi-branch neural networks as described herein may include an input layer, a hidden layer (including with multiple node levels), and an output layer. Moreover, the multi-branch neural networks of the present disclosure may further include architectural and neural network design enhancements that can improve the effectiveness of processing multi-layer ICs for defect prediction. Different layers of an IC design may be modeled by separate and distinct architectural components of a multi-branch neural network, referred to herein as neural network branches. As an example shown in FIG. 2, the multi-branch neural network 200 includes separate branches 201-203, each of which may model a different layer of an IC design. The branches 201-203 may be similarly structured and configured, but specifically to process, analyze, or model geometry effects and other layer-specific interactions for distinct design layers of an IC design.

As such, the layer-of-interest branch 201 of the multi-branch neural network 200 may be configured to process, analyze, or model a layer-of-interest for an IC design, and the additional design layer branches 202 and 203 may be likewise configured for other design layers of the IC design. The multi-branch neural network engine 110 may implement design layer branches as distinct sub-networks of a multi-branch neural network. As such, the layer-of-interest branch 201 may include a number of nodes that form an input layer for the layer-of-interest branch 201 as well as a hidden layer and output layer for the layer-of-interest branch 201. Note that as the layer-of-interest branch 201 may be a sub-component of the multi-branch neural network 200, the output layer of the layer-of-interest branch 201 may be part of the overall hidden layer of the multi-branch neural network 200. In a consistent manner, the multi-branch neural network engine 110 may implement the additional design layer branches 202 and 203 with respective input hidden, and output layers.

The multi-branch neural network engine 110 may implement design layer branches of multi-branch neural networks in any manner supportive of defect predictions for IC designs. In some implementations, input nodes of a given design layer branch may be configured to receive, as inputs, feature vectors representative of a various sections of a corresponding IC design layer. In such examples, feature extraction for a given design layer may include partitioning the given IC design layer, such as by partitioning a physical layout of the given IC design layer (or image thereof) and computing a feature vector for each partition of the given IC design layer. Feature vector computation contemplated herein may take any number of forms, from extracting density-based features for design layer partitions, vector-based representations of geometric features, and the like. Any suitable technique to extract feature vectors from physical layouts or geometric representations of a IC design layer may be utilized herein to generate inputs for design layer branches of multi-branch neural networks.

In some implementations, an input layer of a design layer branch implemented by the multi-branch neural network engine 110 may include a number of input nodes equal to the number of partitions of a corresponding IC design layer. Variations and customizations based on design layer partition numbers, efficiency, geometric partitioning precision, and any other suitable parameter may be weighed in design layer branch configurations. Thus, for a design layer branch including 1,000 input nodes, inputs to the design layer branch may, in some examples, be provided by partitioning a high-resolution image of a physical layout of a corresponding IC design layer into 1,000 partitions (e.g., 1,000 rectangular image partitions, which can be equal in size) and generating 1,000 feature vectors based on the geometric features included in the 1,000 partitions. Any configurable number of input nodes to design layer branches are contemplated herein. In a consistent manner, input layers of additional design layer branches can be configured in multi-branch neural networks. Together, the input nodes of the multiple design layer branches may form an input layer for a multi-branch neural network. In the example of FIG. 2, the input nodes of the layer-of-interest branch 201, the additional design layer branch 202, and the additional design layer branch 203 together form the input layer of the multi-branch neural network 200.

The multi-branch neural network engine 110 may implement the hidden layer and output layer of design layer branches in any suitable manner. In some implementations, the output layer of each design layer branch in multi-branch neural networks maybe configured to correspond to specific output features that characterize a given IC design layer. Such output features may be configured through user-input or configuration, and the multi-branch neural network engine 110 may support any suitable configuration for output layers, e.g., through specific output nodes that form the output layer of design layer branches.

In some implementations, the multi-branch neural network engine 110 may configure the output layer of design layer branches to correspond to specific a hidden layer phase (e.g., level) of the overall multi-branch neural network, which includes a specifically configured output layer for the multi-branch neural network. Accordingly, the multi-branch neural network engine 110 need not implement the output layers of the design layer branches to include specific or preconfigured output features of a design layer. Instead, the output nodes of each design layer may represent internal, hidden layer nodes of a multi-branch neural network. To illustrate through the example of FIG. 2, the multi-branch neural network 200 is configured with output layer that includes a single output node (shown in FIG. 2 as the output node of the merged branch 204 of the multi-branch neural network 200). The multi-branch neural network 200 may include multiple hidden layer node levels comprising levels of neural network neurons between the input layer (e.g., the input nodes of the design layer branches 201-203) and the output node of the merged branch 204. The output layers of the design layer branches 201-203 may take the form of a node level in the hidden layer of the multi-branch neural network 200, with each respective output layer of the design layer branches 201-203 corresponding to hidden layer nodes specific to a different IC design layer of an IC design.

To consider the impact of multiple layers in the IC design, the multi-branch neural network engine 110 may merge design layer branches of multi-branch neural networks. As one way to do so, the multi-branch neural network engine 110 may implement multi-branch neural networks that merge multiple design layer branches into a merged branch, such as the merged branch 204 shown in the multi-branch neural network 200 of FIG. 2. The merged branch 204 may likewise be a sub-component, e.g., a distinct branch, in the multi-branch neural network 200, and include an input layer, a hidden layer (though, in some cases and if configured, without a hidden layer), and an output layer. The output layer of the merged branch 204 may form the output layer of the multi-branch neural network 200, and the input layer and hidden layer of the merged branch 204 may be part of the hidden layer of the multi-branch neural network 200. The merged branch 204 need not be limited to a single level to merge design layer branches of a multi-branch neural network. In some implementations, the merged branch 204 may be comprised of multiple levels of internal sub-branches that may merge together different layers at different levels in merged branch 204.

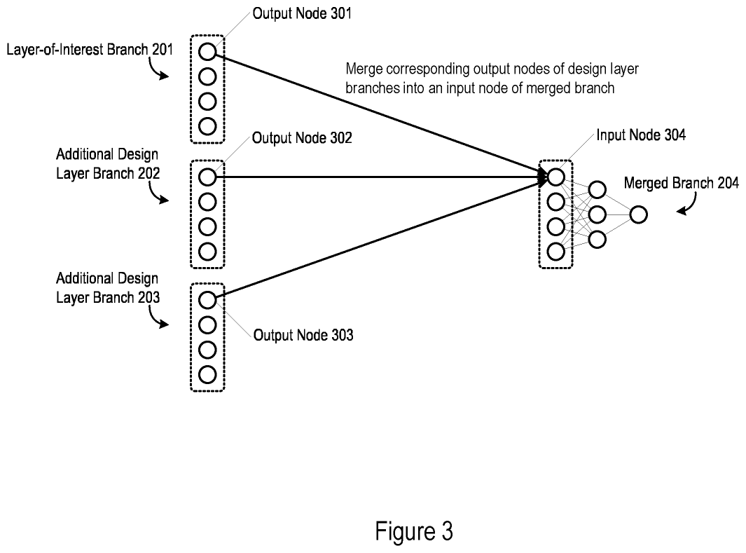

Multi-branch neural networks of the present disclosure may merge multiple design layer branches into a merged branch in various ways and at varying levels in a given merged branch. As one example, the multi-branch neural network engine 110 may implement multi-branch neural networks in which output nodes of a layer-of-interest branch and additional design layer branches merge into an input node of the merged branch. Example features of such merging are described next with reference to FIG. 3.

FIG. 3 shows an example architecture in which multiple output nodes of design layer branches are merged into a corresponding input node of a merged branch of a multi-branch neural network. The example of FIG. 3 is provided through the example output layers shown for the layer-of-interest branch 201 and additional design layer branches 202 and 203 as well as the input layer of the merged branch 204 of FIG. 2. A multi-branch neural network may merge individual output nodes of multiple different design layer branches into a single input node of a merged branch. As shown in FIG. 3, various output nodes of design layer branches are illustrated, including an output node 301 of the layer-of-interest branch 201, an output node 302 of the additional design layer branch 202, and an output node 303 of the additional design layer branch 203. The example architecture of FIG. 3 merges the output nodes 301-303 of the design layer branches 201-203 into a single node of a merged branch, shown as the input node 304 of the merged branch 204.

The multi-branch neural network technology of the present disclosure may merge nodes in any suitable manner. For instance, the multi-branch neural network engine 110 may implement the multi-branch neural network wherein an input value to the input node 304 of the merged branch 204 is computed as a function of values of the output nodes 301-304 of the layer-of-interest branch 201 and the additional design layer branches 202 and 203. Example functions may include an averaging function, a convolution function, any configured mathematical operation by which multiple nodes (e.g., neural network neurons) are combined into a single node, or any other suitable function by which to process different values from output nodes of design layer branches.

The multi-branch neural network engine 110 may implement different design layer branches in a consistent manner, such that hidden layer node levels of different design layer branches are consistently configured. As such, the number of output nodes of a given design layer branch may be the same and otherwise consistent as those of other design layer branches in a multi-branch neural network. Individual output nodes of different design layer branches may thus measure, represent, or provide a corresponding feature or neuron value for a particular IC design layer. Merging of such corresponding output nodes of design layer branches may thus provide a combined feature or neuron value for the multiple IC design layers processed, analyzed, or modeled by a multi-branch neural network. To illustrate through FIG. 3, the output nodes 301-303 may represent the same hidden layer node of a neural network (e.g., compute a neuron value in the same way), but for different IC design layers of an IC design (specifically the layer-of-interest and additional design layers to which the design layer branches 201-203 respectively correspond). The merging of the output nodes 301-303 may thus provide a single node value in the multi-branch neural network 200, but a single node that accounts for the various geometries, analysis, and processing of the layer-of-interest as well as the additional design layers.

In a similar manner as for output nodes 301-303, the multi-branch neural network 200 may merge the other output nodes of the design layer branches 201-203 into input nodes for the merged branch 204. As such, the input layer of a merged branch may include a number of input nodes merged from the output layers of design layer branches of a multi-branch neural network. The hidden layer phase or level at which design layer branches are merged into the merged branch may be configured, for example tuned through experimentation and neural network training to improve results or circuit analysis capabilities. A merged branch may process the input values provided through its input layer and generate an output according to the configured output layer for a multi-branch neural network. Output layers of multi-branch neural networks may comprise any number of output values for a multi-branch neural network, such as predictor values for an IC design computed based on the layer-of-interest branch and additional design layer branches. In the example of FIGS. 2 and 3, the merged branch 204 provides an output layer comprised of a single output node. The single output node may provide a predictor value for any suitable analysis of an IC design, such as critical dimension value for a point-of-interest on a layer-of-interest in an IC design.

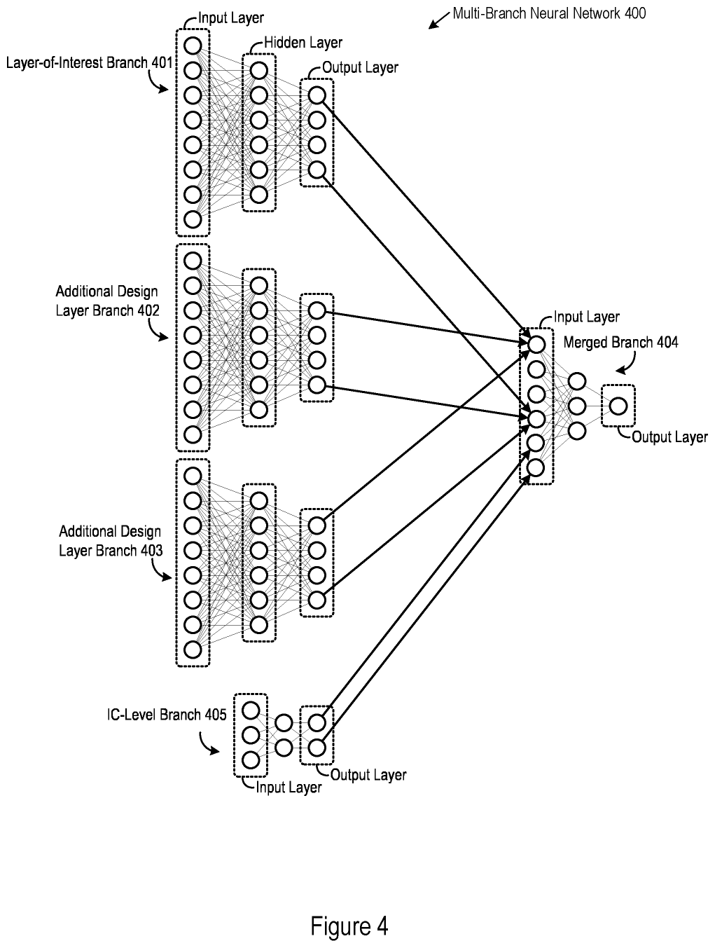

As described herein, the multi-branch neural network technology of the present disclosure can provide capabilities for a neural network to account the geometry of multiple different IC design layers. Additional IC design layers beyond a layer-of-interest can be modeled, processed, and analyzed through distinct neural network branches of a multi-branch neural network and eventually merged to into a merged layer. As another feature of the multi-branch neural network technology described herein, other aspects of an IC design can be accounted for as well in generating predictor values for the IC design. Such aspects of the IC design may not be layer-specific, such as IC-wide design features of the IC design. Such features of an IC design may also be accounted for in neural network output generations, and example features of such are described next with reference to FIG. 4.

FIG. 4 shows an example of a multi-branch neural network 400 that includes an IC-level branch separate from design layer branches of the multi-branch neural network. The multi-branch neural network 400 of FIG. 4 includes a layer-of-interest branch 401, an additional design layer branch 401, and another additional design layer branch 403 that merge into a merged branch 404 similar to that of the multi-branch neural network 200 of FIG. 2. The multi-branch neural network 400 also includes an IC-level branch 405. The IC-level branch 405 may model, process, or analyze any number of aspects of an IC design that are not specific to a particular layer of the IC design.

Instead, the IC-level branch 405 may take inputs that are specific to the overall IC design, such a number of total design layers, technology node size, lithographical characteristics applicable to the IC design, or any other suitable feature or aspect of the IC design. That is, the inputs to an IC-level branch 405 may be general to the IC design itself, instead of specific to a particular IC design layer or varying in value between IC design layers. The multi-branch neural network 400 may implement the IC-level branch 405 as a distinct sub-architecture component of the multi-branch neural network 400, and the IC-level branch 405 may include its own input layer, hidden layer, and output layer. The input nodes of the IC-level branch 405 may be part of the overall input layer of the multi-branch neural network 400 (e.g., together with the input nodes of the design layer branches 401-405), and the hidden layer and output layer of the IC-level branch 405 may be part of the overall hidden layer of the multi-branch neural network 400.

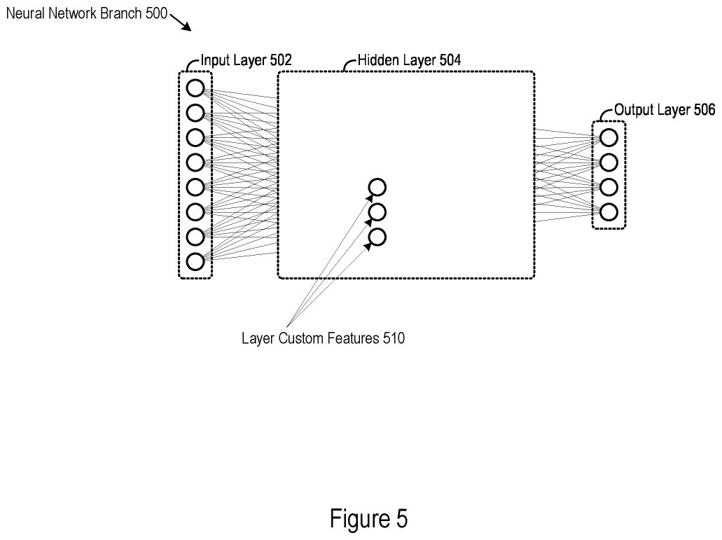

As the inputs to the IC-level branch 405 are not specific to a given design layer, output nodes of the IC-level branch 405 need not be merged with other layer-specific output nodes. Instead, the output nodes of the IC-level branch 405 may be provided directly as input nodes into the merged branch. Although illustrated as a two-node set in both the output layer of the IC-level branch 405 and the input layer of the merged branch 404, these nodes may be the same and need not be reproduced or replicated at different levels or layers of different sub-architecture components of the multi-branch neural network 400. In any of the ways described herein, multi-branch neural networks may account through generic features of an IC design through IC-level branches. Thus, the multi-branch neural network technology of the present disclosure may account for additional aspects of an IC level design beyond layer geometry of multiple design layers of the IC design. As another feature, the multi-branch neural network technology of the present disclosure may account for non-geometric features that are layer-specific, doing through layer customer features. Examples of such are described next with reference to FIG. 5.

FIG. 5 shows an example neural network branch 500 that includes layer custom features. The neural network branch 500 shown in FIG. 5 may be any design layer branch implemented by a multi-branch neural network, and layer custom features may be utilized to account for layer-specific features that can be customized based on user selection, experimentation, or any suitable configuration scheme. As the neural network branch 500 may take the form of a design layer branch, the input layer 502 of the neural network branch 500 may be in form of input nodes that receive (or, in some implementations, compute) feature vectors of design layer partitions based on the geometry of the design layer partitions. The neural network branch 500 may also include a hidden layer 504 that processes the inputs of the IC design layer (e.g., the computed feature vectors for the design layer partitions) and an output layer 506. As noted herein, the output layer 506 may be comprised of a preconfigured output nodes with specific features, aspects, or attributes of the IC design layer. As another implementation, the output layer 506 may be formed of hidden layer nodes of an overall multi-branch neural network at a particular hidden layer level or phase at which the hidden layer nodes specific to the IC design layer are merged with corresponding nodes of other IC design layers.

The neural network branch 500 may include neural network nodes (e.g., neurons) configured to receive or otherwise process non-geometric features of the IC design layer. In the example of FIG. 5, the neural network branch 500 includes neural network nodes for custom layer features 510. Such custom layer features 510 may include, as examples, non-geometric features that are specific to a given IC design layer. Example custom layer features may thus include distance-based features of the IC design layer (e.g., distance to a closest contact or closest via), and such distance-based features may include direction (and thus be represented as vectors) or any other suitable measure for the IC design layer. Any suitable or relevant aspect of an IC design layer may be specified as a custom layer feature 510, whether through user-selection, preconfigured parameters, or combinations thereof.

Through the custom layer features 510 may be provided as inputs to multi-branch neural network, the neural network branch 500 need not receive the custom layer features 500 as part of the input layer of the multi-branch neural network (e.g., via the input layer 502 of the neural network branch), though such implementations are certainly possible and contemplated herein. Instead, in the example of FIG. 5, the neural network branch 500 can receive the custom layer features 510 as part of a hidden layer node level with the hidden layer 504 of the neural network branch 500. Doing so may decrease the weight or impact of the custom layer features 510, e.g., as compared to the geometry-based feature vectors of the input layer 502 of the neural network branch 500. Thus, the architecture of the neural network branch 500 may allow for geometry-based inputs to process and analyze an IC design layer as well as custom layer features applied into the analyze further along the hidden layer, so as to account for such custom layer features while weighting the geometric features of the IC design layer with increased priority or influence.

In any combination of the various ways described herein, the multi-branch neural network engine 110 may implement multi-branch neural networks. Through the multi-branch neural network technology of the present disclosure, multiple IC design branches can be accounted for. The specific design of hidden layer nodes (and their processing capability and modeling) can be configured according to any suitable neural network, artificial intelligence, or machine-learning implementation. The multiple branches of the described multi-branch neural networks can be merged together into a merged branch as consistently described herein. Thus, geometric characteristics and effects from multiple IC design layers can be accounted for while generating outputs through an output layer of the multi-branch neural network. Generic IC-level features can be accounted for through a separate IC-level branch and other layer-specific features can be accounted for through custom layer features, in any of the ways described herein.

With the multi-branch neural network architectures described herein, suitable training sets land regression techniques can be applied to support defect prediction in IC designs. Through the multi-branch neural networks of the present disclosure, manufacturing defects can be predicted with increased accuracy and effectiveness. As a multi-branch neural network can be configured to output predictor values for layers-of-interest (and points-of-interest located within a layer-of-interest), an IC design can be considered, processed, and analyzed. The defect prediction engine 112 may support such defect predictions through implemented (e.g., trained) multi-branch neural networks. For an IC design under consideration, the defect prediction engine 112 may generate inputs for the multi-branch neural network specific to the input IC design. For specific design layers (e.g., a layer-of-interest of the input IC design), the defect prediction engine 112 may generate or otherwise access layer specific inputs to provide to the multi-branch neural network. This may include partitioning a high-resolution image of the relevant layers of the input IC design and computing or otherwise accessing feature vectors for the partitioned design layers. The defect prediction engine 112 may similarly access and input custom layer features or any inputs to an IC-level branch specifically for the input IC design.

With the provided inputs for the input IC design, the multi-branch neural network may generate outputs in the form of predictor values for the input IC design. For example, a predictor value may take the form of a critical dimension for a point-of-interest located in the layer-of-interest, and the defect prediction engine 112 may predict a manufacturing defect at the point-of-interest responsive to determination that the critical dimension for the point-of-interest meets a defect criterion, e.g., includes geometry that is lesser than the determined critical dimension. While critical dimension is provided as one example, any suitable predictor value for manufacturing defects is contemplated herein. As the multi-branch neural network takes inputs from multiple different design layers of an IC design, the predictor values computed by multi-branch neural networks may be increasingly accurate, especially as compared to other defect prediction techniques that fail to account for additional IC design layers besides a layer-of-interest. Through multi-branch neural networks of the present disclosure and the various neural network architectures described herein, defect predictions in IC designs can be performed with increased accuracy, efficiency, and effectiveness.

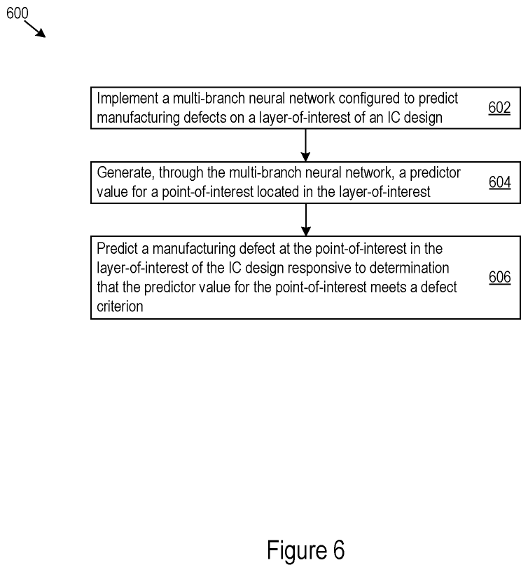

FIG. 6 shows an example of logic 600 that a system may implement to support multi-branch neural networks for defect predictions in IC designs. For example, the computing system 100 may implement the logic 600 as hardware, executable instructions stored on a machine-readable medium, or as a combination of both. The computing system 100 may implement the logic 600 via the multi-branch neural network engine 110 and the defect prediction engine 112, through which the computing system 100 may perform or execute the logic 600 as a method to support defect predictions in IC designs through multi-branch neural networks. The following description of the logic 600 is provided using the multi-branch neural network engine 110 and defect prediction engine 112 as examples. However, other implementation options by computing systems are possible.

In implementing the logic 600, the multi-branch neural network engine 110 may implement a multi-branch neural network configured to predict manufacturing defects on a layer-of-interest of an IC design (602). The implemented multi-branch neural network may include multiple neural network branches, including a layer-of-interest branch that processes inputs of the layer-of-interest, additional design layer branches that process inputs of the other design layers of the IC design different from the layer-of-interest, and a merged branch. The merged branch of the implemented neural network may receive, as inputs, outputs of the layer-of-interest branch that processes the inputs of the layer-of-interest and outputs of the additional design layer branches that process the inputs of the other design layers of the IC design. The merged branch may be configured to output a predictor value for the IC design based on the layer-of-interest branch and the additional design layer branches.

In implementing the logic 600, the defect prediction engine 112 may generate, through the multi-branch neural network, a predictor value for a point-of-interest located in the layer-of-interest (604). The defect prediction engine 112 may further predict a manufacturing defect at the point-of-interest in the layer-of-interest of the IC design responsive to determination that the predictor value for the point-of-interest meets a defect criterion (606).

The logic 600 shown in FIG. 6 provides an illustrative example by which a computing system 100 may support multi-branch neural networks for defect predictions in IC designs according to the present disclosure. Additional or alternative steps in the logic 600 are contemplated herein, including according to any of the various features described herein for the multi-branch neural network engine 110, the defect prediction engine 112, or combinations thereof.

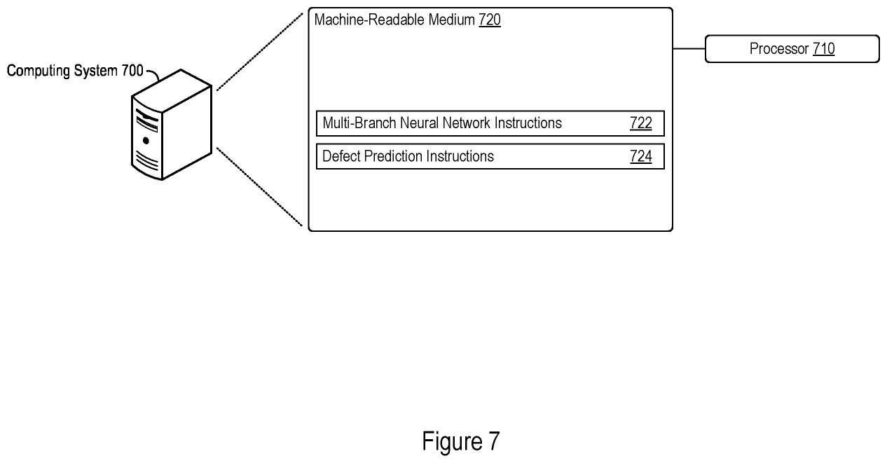

FIG. 7 shows an example of a computing system 700 that supports multi-branch neural networks for defect predictions in IC designs. The computing system 700 may include a processor 710, which may take the form of a single or multiple processors. The processor(s) 710 may include a central processing unit (CPU), microprocessor, or any hardware device suitable for executing instructions stored on a machine-readable medium. The computing system 700 may include a machine-readable medium 720. The machine-readable medium 720 may take the form of any non-transitory electronic, magnetic, optical, or other physical storage device that stores executable instructions, such as the multi-branch neural network instructions 722 and the defect prediction instructions 724 shown in FIG. 7. As such, the machine-readable medium 720 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 700 may execute instructions stored on the machine-readable medium 720 through the processor 710. Executing the instructions (e.g., the multi-branch neural network instructions 722 and the defect prediction instructions 724) may cause the computing system 700 to perform or implement any of the multi-branch neural network technology described herein, including according to any aspect of the multi-branch neural network engine 110, the defect prediction engine 112, or combinations thereof.

For example, execution of the multi-branch neural network instructions 722 by the processor 710 may cause the computing system 700 to implement a multi-branch neural network configured to predict manufacturing defects on a layer-of-interest of an IC design. The implemented multi-branch neural network may include multiple neural network branches, including a layer-of-interest branch that processes inputs of the layer-of-interest, additional design layer branches that process inputs of the other design layers of the IC design different from the layer-of-interest, and a merged branch. The merged branch of the implemented neural network may receive, as inputs, outputs of the layer-of-interest branch that processes the inputs of the layer-of-interest and outputs of the additional design layer branches that process the inputs of the other design layers of the IC design. The merged branch may be configured to output a predictor value for the IC design based on the layer-of-interest branch and the additional design layer branches.

Execution of the defect prediction instructions 724 may cause the computing system 700 to generate, through the multi-branch neural network, a predictor value for a point-of-interest located in the layer-of-interest and predict a manufacturing defect at the point-of-interest in the layer-of-interest of the IC design responsive to determination that the predictor value for the point-of-interest meets a defect criterion.

Any additional or alternative aspects of the multi-branch neural network technology as described herein may be implemented via the multi-branch neural network instructions 722, the defect prediction instructions 724, or any combinations thereof.

The systems, methods, devices, and logic described above, including the multi-branch neural network engine 110 and the defect prediction engine 112, may be implemented in many different ways in many different combinations of hardware, logic, circuitry, and executable instructions stored on a machine-readable medium. For example, the multi-branch neural network engine 110, the defect prediction engine 112, or both, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the multi-branch neural network engine 110, the defect prediction engine 112, or combinations thereof.

The processing capability of the systems, devices, and engines described herein, including the multi-branch neural network engine 110 and the defect prediction engine 112, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples and features have been described above, many more implementations are possible.

1. A method comprising:
by a computing system:
implementing a multi-branch neural network configured to predict manufacturing defects on a layer-of-interest of an integrated circuit (IC) design, wherein the multi-branch neural network comprises multiple neural network branches, including:
a layer-of-interest branch that process inputs from the layer-of-interest;
additional design layer branches that processes inputs from other design layers of the IC design different from the layer-of-interest; and
a merged branch that receives, as inputs, outputs of the layer-of-interest branch that processes the inputs of the layer-of-interest and outputs of the additional design layer branches that process the inputs of the other design layers of the IC design, wherein the merged branch is configured to output a predictor value for the IC design based on the layer-of-interest branch and the additional design layer branches; and
generating, through the multi-branch neural network, a predictor value for a point-of-interest located in the layer-of-interest; and
predicting a manufacturing defect at the point-of-interest in the layer-of-interest of the IC design responsive to determination that the predictor value for the point-of-interest meets a defect criterion.

2. The method of claim 1, comprising implementing the multi-branch neural network wherein output nodes of the layer-of-interest branch and the additional design layer branches merge into an input node of the merged branch.

3. The method of claim 2, comprising implementing the multi-branch neural network wherein an input value to the input node of the merged branch is computed as a function of values of the output nodes of the layer-of-interest branch and the additional design layer branches.

4. The method of claim 1, comprising implementing the multi-branch neural network to further comprise an IC-level branch that accounts for features of the IC design that are not specific to a given design layer of the IC design.

5. The method of claim 1, wherein input nodes of a given neural network branch that models a given design layer of the IC design comprise feature vectors computed from a partitioned image of the given design layer of the IC.

6. The method of claim 1, comprising implementing the multi-branch neural network wherein a given neural network branch that models a given design layer of the IC design account for additional aspects of a given layer through layer custom features implemented in a hidden layer of the given neural network branch.

7. The method of claim 1, wherein the predictor value comprises a critical dimension for the point-of-interest in the layer-of-interest of the IC design.

8. A system comprising:
a processor; and
a non-transitory machine readable medium comprising instructions, that when executed by the processor, causes a computing system to:
implement a multi-branch neural network configured to predict manufacturing defects on a layer-of-interest of an integrated circuit (IC) design, wherein the multi-branch neural network comprises multiple neural network branches, including:
a layer-of-interest branch that process inputs from the layer-of-interest;
additional design layer branches that processes inputs from other design layers of the IC design different from the layer-of-interest; and
a merged branch that receives, as inputs, outputs of the layer-of-interest branch that processes the inputs of the layer-of-interest and outputs of the additional design layer branches that process the inputs of the other design layers of the IC design, wherein the merged branch is configured to output a predictor value for the IC design based on the layer-of-interest branch and the additional design layer branches; and
generate, through the multi-branch neural network, a predictor value for a point-of-interest located in the layer-of-interest; and
predict a manufacturing defect at the point-of-interest in the layer-of-interest of the IC design responsive to determination that the predictor value for the point-of-interest meets a defect criterion.

9. The system of claim 8, wherein the instructions, when executed, cause the computing system to implement the multi-branch neural network wherein output nodes of the layer-of-interest branch and the additional design layer branches merge into an input node of the merged branch.

10. The system of claim 9, wherein the instructions, when executed, cause the computing system to implement the multi-branch neural network wherein an input value to the input node of the merged branch is computed as a function of values of the output nodes of the layer-of-interest branch and the additional design layer branches.

11. The system of claim 8, wherein the instructions, when executed, cause the computing system to implement the multi-branch neural network to further comprise an IC-level branch that accounts for features of the IC design that are not specific to a given design layer of the IC design.

12. The system of claim 8, wherein input nodes of a given neural network branch that models a given design layer of the IC design comprise feature vectors computed from a partitioned image of the given design layer of the IC.

13. The system of claim 8, wherein the instructions, when executed, cause the computing system to implement the multi-branch neural network wherein a given neural network branch that models a given design layer of the IC design account for additional aspects of a given layer through layer custom features implemented in a hidden layer of the given neural network branch.

14. The system of claim 8, wherein the instructions, wherein the predictor value comprises a critical dimension for the point-of-interest in the layer-of-interest of the IC design.

15. A non-transitory machine-readable medium comprising instructions that, when executed by a processor, cause a computing system to:
implement a multi-branch neural network configured to analyze a layer-of-interest of an integrated circuit (IC) design, wherein the multi-branch neural network comprises multiple neural network branches, including:
a layer-of-interest branch that process inputs from the layer-of-interest;
additional design layer branches that processes inputs from other design layers of the IC design different from the layer-of-interest; and
a merged branch that receives, as inputs, outputs of the layer-of-interest branch that processes the inputs of the layer-of-interest and outputs of the additional design layer branches that process the inputs of the other design layers of the IC design, wherein the merged branch is configured to output a predictor value for the IC design based on the layer-of-interest branch and the additional design layer branches; and
generate, through the multi-branch neural network, a predictor value for a point-of-interest located in the layer-of-interest; and
analyze a point-of-interest in the layer-of-interest of the IC design based on the predictor value for the point-of-interest.

16. The non-transitory machine-readable medium of claim 15, wherein the instructions, when executed, cause the computing system to implement the multi-branch neural network wherein output nodes of the layer-of-interest branch and the additional design layer branches merge into an input node of the merged branch.

17. The non-transitory machine-readable medium of claim 16, wherein the instructions, when executed, cause the computing system to implement the multi-branch neural network wherein an input value to the input node of the merged branch is computed as a function of values of the output nodes of the layer-of-interest branch and the additional design layer branches.

18. The non-transitory machine-readable medium of claim 15, wherein the instructions, when executed, cause the computing system to implement the multi-branch neural network to further comprise an IC-level branch that accounts for features of the IC design that are not specific to a given design layer of the IC design.

19. The non-transitory machine-readable medium of claim 15, wherein input nodes of a given neural network branch that models a given design layer of the IC design comprise feature vectors computed from a partitioned image of the given design layer of the IC.

20. The non-transitory machine-readable medium of claim 15, wherein the instructions, when executed, cause the computing system to implement the multi-branch neural network wherein a given neural network branch that models a given design layer of the IC design account for additional aspects of a given layer through layer custom features implemented in a hidden layer of the given neural network branch.
